(19) United States
(12) Patent Application Publication
(10) Pub. No.: US 2002/0056063 A1
(43) Pub. Date: May 9, 2002

(54) Power saving feature during memory self-test

(76) Inventor: John A. Nerl, Londonderry, NH (US)

Correspondence Address: CESARI AND MCKENNA, LLP, 88 BLACK FALCON AVENUE, BOSTON, MA, 02210, US

(21) Appl. No.: 09/864,789

(22) Filed: May 24, 2001

Related U.S. Application Data
(60) Provisional application No. 60/208,149, filed on May 31, 2000.
(60) Provisional application No. 60/208,230, filed on May 31, 2000.

(51) Int. Cl. G06F 13/00; G06F 12/00; G06F 12/14; G06F 12/16; G06F 13/28; G06F 1/26; G06F 1/32; G01R 31/28

(52) U.S. Cl. 714/733; 711/115; 711/170; 713/320

(57) ABSTRACT

A microcontroller is configured to interfaces with one or more dual in line memory modules (DIMMs) over an I²C bus and with a memory controller. The microcontroller efficiently retrieves configuration information from the DIMMs and provides it to the memory controller. During system power-up or reset, the memory configuration information, including power consumption parameters, is loaded by the microcontroller into the memory controller. The memory controller utilizes the power consumption parameters to control the rate at which built-in self test (BIST) operations are performed by the DIMMs, thereby conserving power.

### CROSS-REFERENCE TO RELATED APPLICATIONS

The present application claims priority from the following U.S. Provisional Patent Applications:

Ser. No. 60/208,149, which was filed on May 31, 2000, by John Nerl for a POWER SAVING FEATURE DURING MEMORY SELF-TEST; and

Ser. No. 60/208,230, which was filed on May 31, 2000, by John Nerl for a USE OF A MICROCONTROLLER TO PROCESS MEMORY CONFIGURATION INFORMATION AND CONFIGURE A MEMORY CONTROLLER which are hereby incorporated by reference.

It is also related to U.S. patent application entitled, CONFIGURATION CACHING MECHANISM FOR ACCELERATING POWER-ON OF A LARGE COMPUTER SYSTEM, Ser. No. 09/545,708 filed on Apr. 7, 2000 and assigned to the assignee of the present invention.

### BACKGROUND OF THE INVENTION

1. Field of the Invention

The present invention relates to computer systems and, in particular, to a method for reducing power requirements during a self test of the memory/directory array of a computer system.

2. Background Information

A modular symmetric multiprocessor (SMP) computer system may contain a plurality of field replaceable units (FRUs) such as processor modules, memory modules, a directory module, power supply modules and backplanes. A particular FRU might be removed from the computer system upon the occurrence of, e.g., a failure or upgrade associated with the FRU. Each memory module and directory module may further comprise a plurality of state-of-the-art memory modules, such as dual in-line memory modules (DIMMs) coupled to the module. Here, the memory and directory FRUs function as “carriers” for the DIMMs, where each DIMM is also considered an FRU that is removable from the system.

Each FRU may also include a storage element for storing specific configuration information used to keep track of the FRU. This FRU-specific information may comprise, inter alia, a part number, a serial number, a location and identification of a manufacturer of the FRU, a manufacturing date, and error information detected at various stages of operation of the FRU. The information may be collected from the storage element by a management subsystem over a management bus. An example of such a storage element is an electrically erasable read only memory (EEROM) device, whereas an example of a management bus is the inter-IC or IIC (hereinafter “I²C”) bus available from Signetics/Phillips Corporation.

In the case of the DIMMs described above, the EEROM may further contain timing parameters (or information from which such parameters may be calculated) that define the operational speeds and characteristics of the DIMMs. These parameters are used by a memory/directory controller, which is typically implemented as an application specific integrated circuit (ASIC), to configure the DIMMs and enable access to the EEROM configuration information stored thereon in order to, e.g., meet server management requirements. For example, the timing parameters may include access time to various locations of the DIMMs along with the frequency at which these accesses may be performed. In addition, the configuration information includes the number of banks per DIMM, along with the number of row and column addresses contained therein. Therefore, it is desirable to provide a means for a memory/directory controller ASIC to examine the timing parameters to insure that the particular DIMMs meet system requirements.

Disadvantages of incorporating an I²C interface into an ASIC includes incurring royalty payments for the proprietary interface, and incurs the risk of re-fabricating the ASIC if interface changes should be required. Yet many conventional microprocessors include I²C bus interface capabilities. By advantageously using these capabilities, the circuit designer can “offload” preprocessing (from the ASIC) of the configuration information received from the DIMMs upon power-up. Moreover, incorporating I²C bus capabilities on a microcontroller enables dynamic implementation of changes to the I²C interface. In contrast, if such capabilities were included in the ASIC, it would be very expensive to “spin” (i.e., reconstruct) another ASIC if a problem were to arise. Therefore, the present invention is directed to a means for efficiently utilizing a microcontroller having I²C bus capabilities for interfacing between a DIMM module and an ASIC for purposes of retrieving configuration information from the DIMMs.

### SUMMARY OF THE INVENTION

The invention includes an asynchronous interface between a custom device and a microcontroller, each capable of retrieving information from a memory of a multiprocessor system. The microcontroller interfaces with the DIMM over an I²C bus, where a protocol efficiently utilizes data and control paths between the microcontroller and the memory controller for purposes of efficiently retrieving configuration information from the DIMMs.

During system power-up or reset, memory configuration information is typically loaded into the memory controller. The microcontroller initiates a sequence to read pertinent electrically erasable read only memory (EEROM) locations on the DIMM to thereby allow the system to perform generic control status register (CSR) read operations for a particular module/system configuration. The microcontroller sequences through the required DIMM configuration locations and performs a level of checking, determines a polynomial to be loaded for each installed array based on the DIMM configuration and stores the information in its local RAM. Once all information is processed, an ASIC control status register write sequence is initiated via the improved asynchronous interface.

### BRIEF DESCRIPTION OF THE DRAWINGS

The above and further advantages of the invention may be better understood by referring to the following description in conjunction with the accompanying drawings, in which like reference numbers indicated identical or functionally similar elements:

FIG. 1 is a schematic block diagram of a modular, symmetric multiprocessing (SMP) system having a plurality of Quad Building Block (QBB) nodes and an input/output (I/O) subsystem interconnected by a hierarchical switch (HS);

FIG. 2 is a schematic block diagram of a QBB node of FIG. 1;

FIG. 3 is a schematic block diagram of the I/O subsystem of FIG. 1;

FIG. 4 is a schematic block diagram of a console serial bus (CSB) subsystem within the SMP system of FIG. 1;

FIG. 5 is a schematic block diagram of various agents, including a system control manager (SCM) coupled to a Peripheral Computer Interconnect (PCI) backplane of a PCI drawer;

FIG. 6 is a schematic block diagram of various agents, including a power system manager (PSM) module coupled to a QBB backplane of the QBB node of FIG. 2;

FIG. 7 is a schematic block diagram of the power system manager 610 module including I²C buses and devices;

FIG. 8 is a schematic block diagram of circuitry contained on a memory/directory module (MDM) carrier of the SMP system, including a MDM memory controller ASIC that may be advantageously used with the present invention; and

FIG. 9 is a schematic block diagram showing the internals of the MDM memory controller ASIC in accordance with the present invention.

### DETAILED DESCRIPTION OF AN ILLUSTRATIVE EMBODIMENT

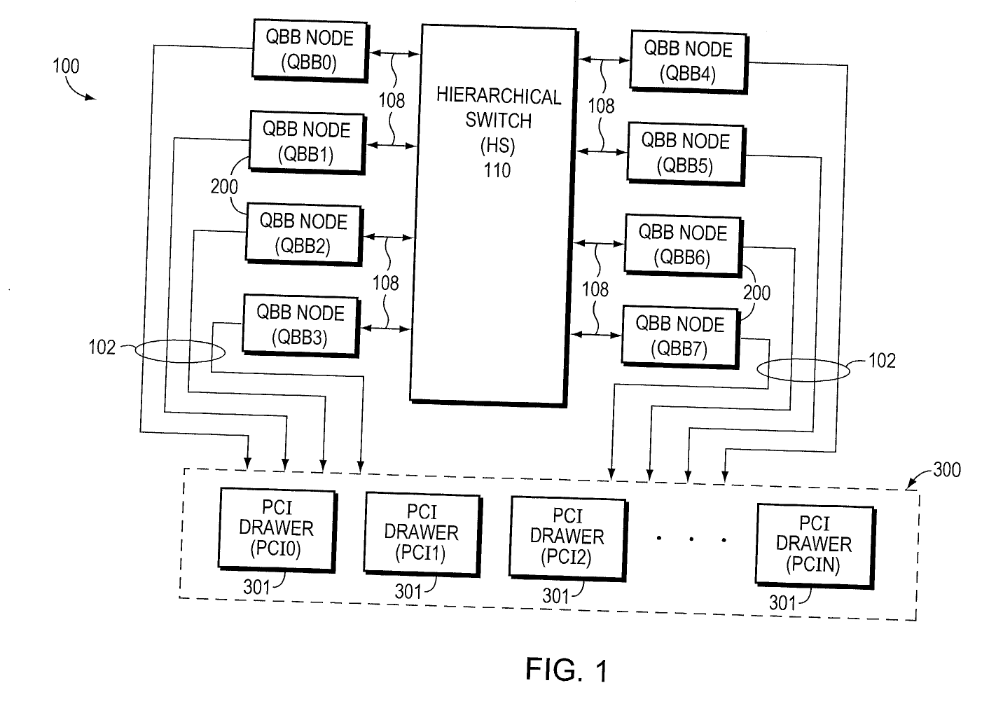

FIG. 1 is a schematic block diagram of a modular, symmetric multiprocessing (SMP) system 100 having a plurality of nodes interconnected by a hierarchical switch 110. The SMP system 100 also includes an input/output (I/O) subsystem 300 comprising a plurality of I/O enclosures (denoted as PCI drawers 301) configured to accommodate a plurality of I/O buses that preferably operate according to the conventional Peripheral Computer Interconnect (PCI) protocol. The PCI drawers 301 are connected to the nodes through a plurality of I/O interconnects (denoted as I/O hoses 102).

In the illustrative embodiment described herein, each node is implemented as a Quad Building Block (QBB) node 200 comprising, inter alia, a plurality of processors, a plurality of memory modules, a directory, an I/O port, a plurality of I/O risers, and a global port interconnected by a local switch as described in greater detail below. Each memory module may be shared among the processors of a local QBB node 200 and, further, among the processors of remote QBB nodes 200 configured on the SMP system 100 to create a distributed shared memory environment. A fully configured SMP system 100 preferably includes eight QBB nodes 200 (denoted as QBB0-QBB7), each of which is coupled to the hierarchical switch 110 by a full-duplex, bi-directional, clock forwarded hierarchical switch link 108.

Data is transferred between the QBB nodes 200 of the SMP system 100 in the form of packets. In order to provide the distributed shared memory environment, each QBB node 200 is configured with an address space, and a directory for the address space. The address space is generally divided into memory address space and I/O address space. The processors and I/O port of each QBB node 200 utilize private hardware caches to store data for memory-space addresses; I/O space data is generally not “cached” in the private caches.

QBB Node Architecture

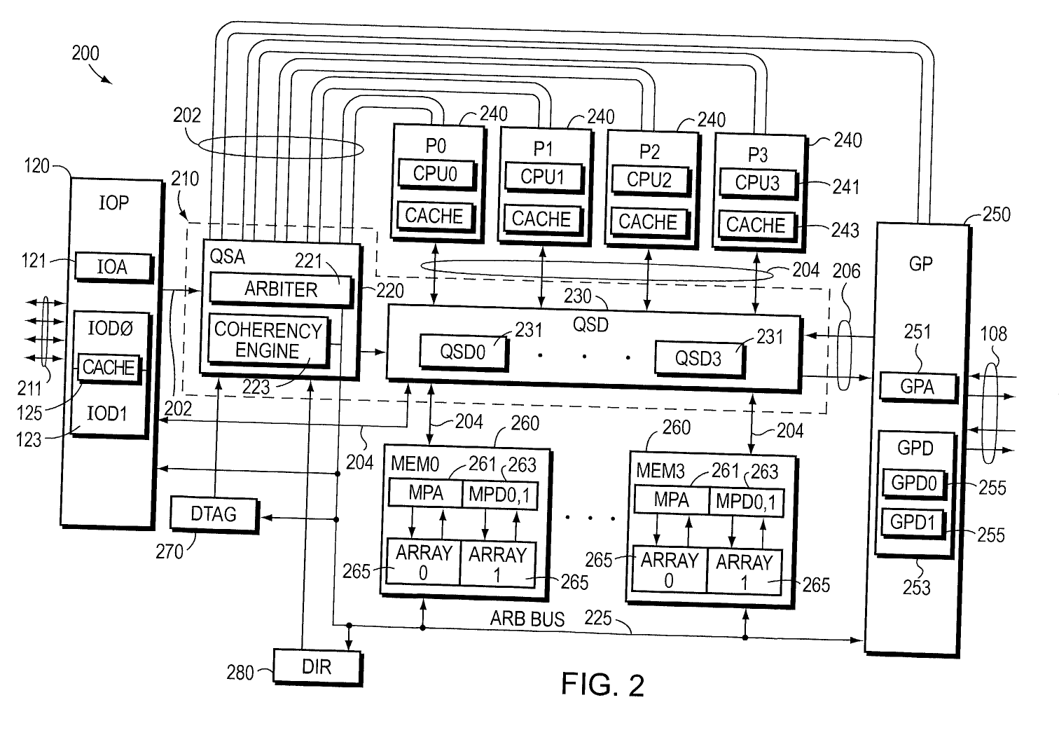

FIG. 2 is a schematic block diagram of the QBB node 200 showing a plurality of processors 240 (denoted as P0-P3) coupled to an I/O port 120, a global port 250, and a plurality of memory modules 260 (denoted as MEM0-MEM3) by a local switch 210. The memory may be organized as a single address space that is shared by the processors 240 and apportioned into a number of blocks, each of which may include, e.g., 64 bytes of data. The I/O port 120 controls the transfer of data between external devices connected to the PCI drawers 301 (FIG. 1) and the QBB node 200 via the I/O hose 102 (FIG. 1). Data is transferred among the components or FRUs of the QBB node 200 in the form of packets.

Each processor 240 includes a central processing unit 241 (CPU) that preferably incorporates a traditional reduced instruction set computer (RISC) load/store architecture. In the illustrative embodiment described herein, the CPUs 241 are Alpha® 21264 processor chips manufactured by Compaq Computer Corporation, although other types of processor chips may be advantageously used. The load/store instructions executed by the processors 240 are issued to the system as memory references, e.g., read and write operations. Each operation may comprise a series of commands (or command packets) that are exchanged between the processors 240 and the SMP system 100.

In addition, the I/O port 120 includes a private cache 125 and each processor 240 includes a private cache 243 for storing data determined likely to be accessed in the future. The caches 243 are preferably organized as write-back caches apportioned into, e.g., 64-byte cache lines accessible by the processors 240; it should be noted, however, that other cache configurations, such as write-through caches, may be advantageously used. It should be further noted that memory reference operations issued by the processors 240 are preferably directed to a 64-byte cache line granularity. Since the I/O port 120 and the processors 240 may update data in their respective private hardware caches 125 and 243 without updating shared memory, a cache coherence protocol is utilized to maintain data consistency among the caches .

In the illustrative embodiment, the logic circuits of each QBB node 200 are preferably implemented as application specific integrated circuits (ASICs). For example, the local switch 210 comprises a quad switch address 220 ASIC and a plurality of quad switch data 231 ASICs (denoted as QSD0-QSD3) found in a quad switch data module 230. The quad switch address 220 receives command/address information (requests) from the processors 240, the global port 250, and the I/O port 120, and returns command/address information (control) to the processors 240 and global port 250 via 14-bit, unidirectional links 202. The quad switch data module 230, on the other hand, transmits and receives data to and from the processors 240, the I/O port 120, and the memory modules 260 via 64-bit, bi-directional links 204.

Each memory module 260 includes a memory interface logic circuit comprising a memory port address 261 ASIC and a plurality of memory port data 263 ASICs. The memory port data 263 ASICs are coupled to a plurality of arrays 265 that preferably comprise state-of-the-art memory modules, such as synchronous dynamic random access memory (SDRAM) dual in-line memory modules (DIMMs). Each array 265 comprises a group of four SDRAM DIMMs that are accessed by an independent set of interconnects as described in greater detail below. In this configuration, the memory module 260 functions as a “carrier” for the SDRAM DIMMs.

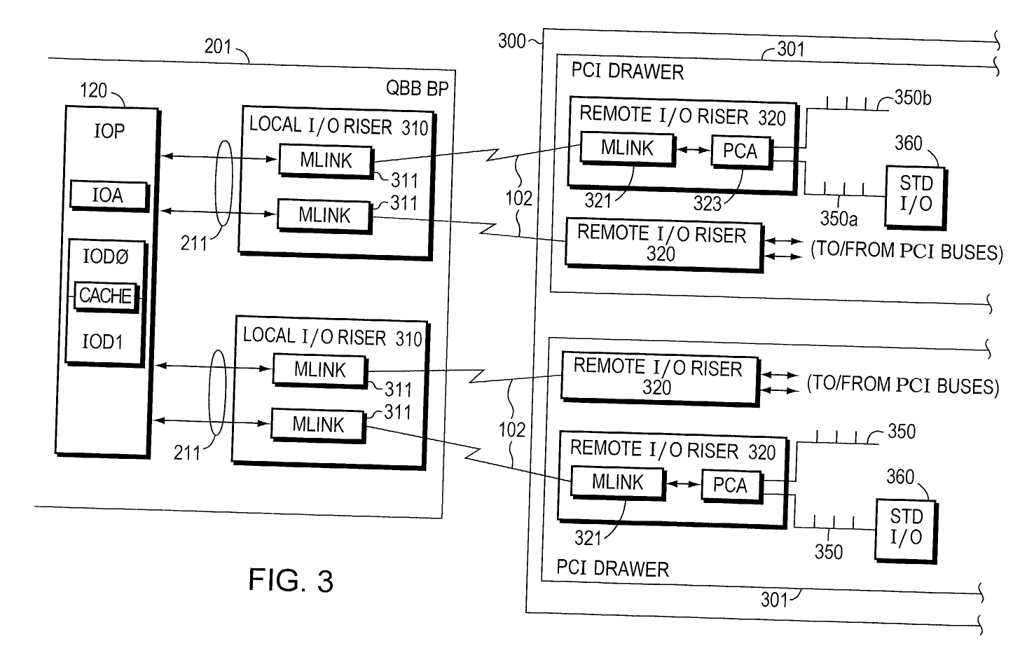

The I/O port 120 preferably comprises an I/O address 121 ASIC and a plurality of I/O data 123 (denoted as IOD0-IOD1) ASICs that collectively provide an I/O port interface from the I/O subsystem to the QBB node 200. Specifically, the I/O port 120 is connected to a plurality of local I/O risers 310 (shown in FIG. 3) via I/O port connections 211, while the I/O address 121 is connected to an I/O port controller of the quad switch address 220, and the I/O data 123 are coupled to an I/O port interface circuit of the quad switch data module 230. In addition, the global port 250 comprises a global port address 251 ASIC and a plurality of GP data 255 ASICs (denoted as GPD0-GPD1) on a global port data module 253. The global port 250 is coupled to the quad switch data module 230 via unidirectional, clock forwarded GP links 206. The global port 250 is further coupled to the hierarchical switch 110 via the hierarchical switch links 108.

A plurality of shared data structures is provided for capturing and maintaining status information corresponding to the states of data used by the QBB nodes 200 of the SMP system 100. One of these structures is configured as a duplicate tag store 270 that cooperates with the individual hardware caches of the SMP system 100 to define the coherence protocol states of data in the QBB node 200. The other structure is configured as a directory 280 to administer the distributed shared memory environment including the other QBB nodes 200 in the SMP system 100. The protocol states of the duplicate tag store 270 and directory 280 are further managed by a coherency engine 223 of the quad switch address 220 that interacts with the duplicate tag store 270 and the directory 280 to maintain coherency of cache lines in the SMP system 100. That is, the duplicate tag store 270 captures the state for the QBB node 200 coherence protocol, while the directory 280 captures the coarse state for the SMP system 100 protocol. The duplicate tag store 270 and the directory 280 interface with the global port 250 to provide coherent communication between the QBB nodes 200 coupled to the hierarchical switch 110.

The duplicate tag store 270, the directory 280, the coherency engine 223, the I/O port 120, the global port 250, and the memory modules 260 are interconnected by a logical serial bus, denoted as an arbiter bus 225. Memory and I/O reference operations issued by the processors 240 are routed over the arbiter bus 225 by an arbiter 221 of the quad switch address 220. The coherency engine 223 and the arbiter 221 are preferably implemented as a plurality of hardware registers and combinational logic configured to produce sequential logic circuits, such as state machines. It should be noted, however, that other configurations of the coherency engine 223, the arbiter 221, the duplicate tag store 270, and the directory 280 may be advantageously used herein.

FIG. 3 is a schematic block diagram showing the I/O subsystem 300. A plurality of local I/O risers 310 and remote I/O risers 320 are interconnected by the I/O hoses 102. The local I/O risers 310 are coupled directly to QBB backplanes 201 of the QBB nodes 200, while the remote I/O risers 320 are contained within the PCI drawers 301 of the I/O subsystem 300. In the illustrative embodiment, each local I/O riser 310 includes two local Mini-Link copper hose interface 311 (MLINK) ASICs that couple the I/O port connections 211 to the QBB ends of the I/O hoses 102. Each local I/O riser 310 is preferably “hot-swappable” and thus includes a presence signal and a storage element used to identify the type of module plugged into an associated I/O riser connector, as described in greater detail below.

Each PCI drawer 301 includes two remote I/O risers 320, each comprising one remote MLINK 321 that connects to the PCI end of the I/O hose 102. The I/O hose 102 comprises a “down-hose” path and an “up-hose” path to enable a full duplex, flow controlled data path between the PCI drawer 301 and the I/O port 120. The remote MLINK 321 also couples to a PCI bus interface 323 ASIC that spawns two PCI buses 350a and 350b. The first PCI bus 350a has three slots and the second PCU bus 350b has four slots for accommodating I/O devices, such as PCI adapters. The first slot of the first PCI bus 350a is preferably reserved for a standard I/O module 360, described in greater detail below.

Console Serial Bus Subsystem

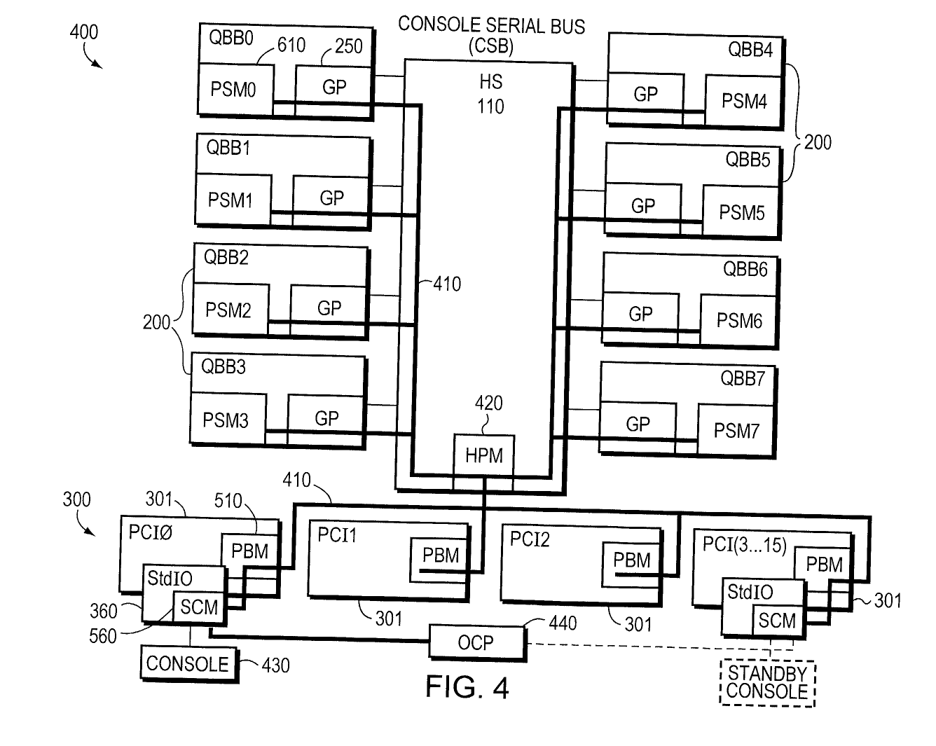

The SMP system 100 also includes a console serial bus subsystem 400, shown in FIG. 4, that manages various power, cooling and clocking sequences for the subsystems within the SMP system 100 to, inter alia, discharge system management functions directed to FRUs of the SMP system 100. In particular, the console serial bus subsystem 400 is responsible for managing power-up and environmental parameters associated with the FRUs, handling “hot-swap” of the FRUs, and conveying relevant status and inventory information about the FRUs to designated processors of the SMP system.

The console serial bus subsystem 400 includes a console serial bus 410 that extends throughout the SMP system 100 interconnecting each of the QBB nodes 200 with the I/O subsystem 300. The console serial bus 410 is preferably a 4-wire interconnect linking a network of microcontrollers located within each PCI drawer 301 and each QBB node 200 coupled to the hierarchical switch 110. The console serial bus subsystem 400 operates on an auxiliary voltage (Vₐᵤₓ) supply to “bring-up” (i.e., power) the microcontrollers to thereby enable communication over the console serial bus 410 in accordance with a serial protocol. An example of a serial protocol that may be advantageously used with the present invention is the transport protocol provided by Cimetrics, Inc. The microcontrollers are responsible for gathering and managing configuration information pertaining to each FRU within each subsystem.

The microcontrollers include a power system manager 610 residing on the QBB backplane 201 of each QBB node 200, a hierarchical switch power manager 420 residing on the hierarchical switch 110, a PCI backplane manager 510 coupled to the PCI backplane of each PCI drawer 301, and at least one system control manager 560 of the I/O subsystem. Broadly stated, the system control manager 560 interacts with the various microcontrollers of the console serial bus subsystem 400 in accordance with a master/slave relationship over the console serial bus 410. For example, the “master” system control manager 560 may instruct “slave” microcontrollers (e.g., the power system manager 610, the hierarchical switch power manager 420, the PCI backplane manager 510) to monitor their respective subsystems to retrieve status information pertaining to the FRUs in order to facilitate system management functions. To that end, one or more microcontrollers (such as the power system manager 610) may provide instructions to other microcontrollers, described herein, over the console serial bus 410 in accordance with a master/slave relationship.

As part of its management functions, the system control manager 560 provides an operator command line interface on local and modem ports of the SMP system 100, while monitoring operator control panel switches and displaying system state information on an operator control panel 440. The system control manager 560 further provides remote system management functions including system-level environmental monitoring operations as well as power on/off, reset, halt, and fault functions associated with the operator control panel 440. In addition, the system control manager 560 interfaces with a system reference manual console application executing on a system processor of the QBB node 200. The system control manager 560 preferably resides on the standard I/O module 360 and shares a communication port with a system reference manual console 430.

The system reference manual console 430 operates at a command-level syntax to provide system management functions (such as boot, start-up and shutdown functions). Operating system calls are issued to the system reference manual console 430 and manifested through a data structure arrangement to enable communication with the system control manager 560. In the illustrative embodiment, the system reference manual console software interfaces with the console serial bus subsystem 400 through the system control manager 560 and, in particular, through a dual-ported, shared RAM to convey status information to an operating system executing on the processor. For example if the power system manager 610 of a QBB node 200 identifies a power system event (e.g., a cooling fan failure), it may convey that event to the operating system so that it may be recorded in an error log to enable corrective action. As described herein, the system control manager 560 interrogates the power system manager 610 to obtain the error event. Thereafter, the system control manager 560 may communicate that status through the dual-ported, shared RAM structure to the system reference manual console 430. The system reference manual console 430 may then relay the error information to the operating system for recording in the error log.

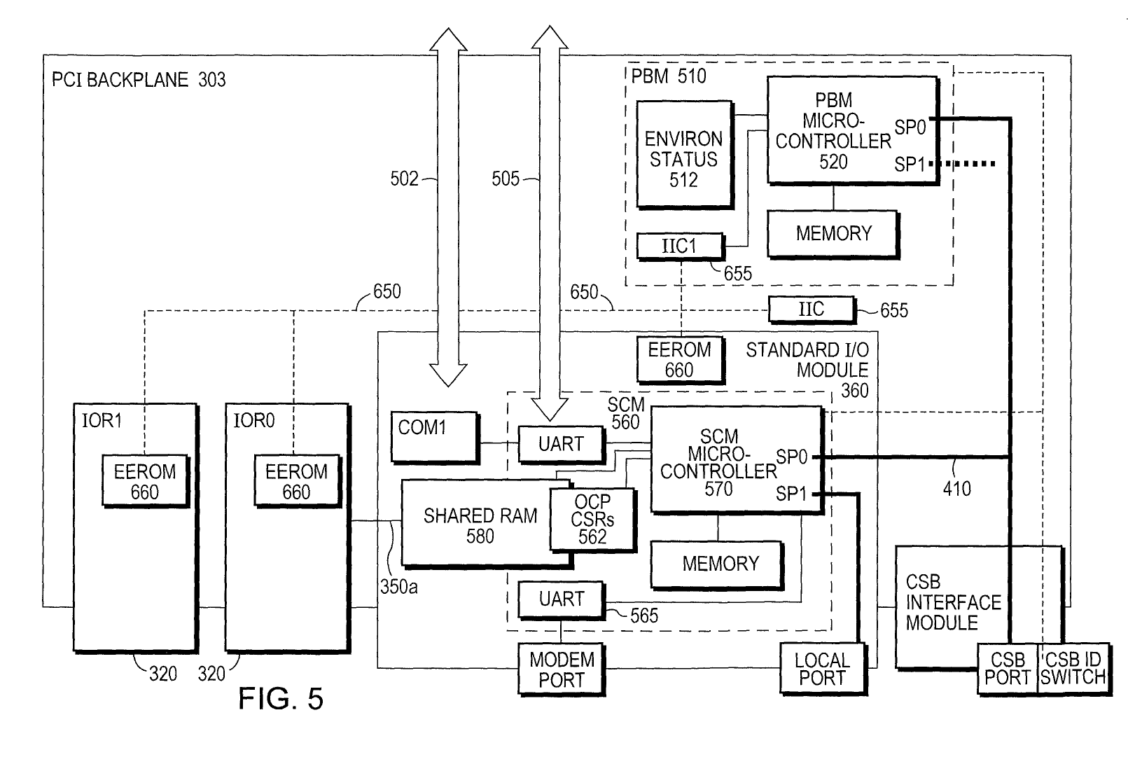

FIG. 5 is a schematic block diagram of various FRUs coupled to a PCI backplane 303 of a PCI drawer 301. The PCI backplane 303 accommodates a PCI backplane manager 510 and a plurality of the remote I/O risers 320 (denoted as IOR0-IOR1). Controllers for various load devices, such as floppy and CD disk drives, are coupled to the standard I/O module 360 over a peripheral I/O bus 502. The standard I/O module 360 also comprises a system control manager microcontroller 570 and a shared RAM 580 for communicating with the system reference manual console 430.

In the illustrative embodiment, each system control manager 560 and PCI backplane manager 510 comprises an AM186ES microcontroller and various memory devices. The system control manager 560 further includes control status registers 562 for communicating with the operator control panel 440, along with universal asynchronous receivers and transceiver (UART) circuitry 565 for communicating with various devices in the system, such as via an asynchronous bus 505. The PCI backplane manager 510, on the other hand, includes a data structure 512 configured to accommodate environmental status control parameters. As noted, the system control manager microcontroller 570 functions as a master microcontroller when communicating with slave microcontrollers over the console serial bus 410 to manage the console serial bus subsystem 400. As part of its console serial bus management function, the system control manager 560 interfaces to the console serial bus 410 to interrogate the environmental status control parameters in order to determine their status.

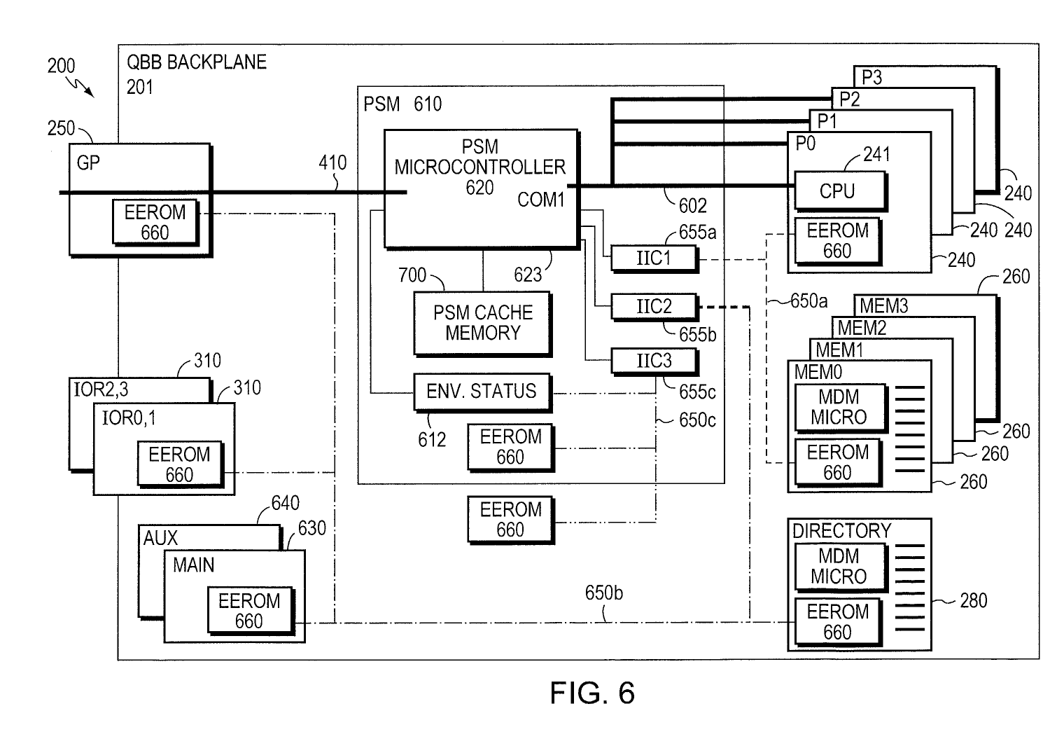

FIG. 6 is a schematic block diagram of various FRUs of a QBB node 200, including the QBB backplane 201. The QBB backplane 201, in turn, supports a plurality of FRUs including the processor modules 240 (P0-P3), the memory modules 260 (MEM0-MEM3), the directory 280, a main power module 630, an auxiliary power module 640, the local I/O riser modules 310 (IOR0-IOR3), the global port 250, and a power system manager module 610. In the illustrative embodiment, the power system manager module 610 comprises an AM186ES microcontroller 620, at least one cache memory 700, and a data structure 612 for storing environmental status control parameters.

In addition, the power system manager microcontroller 620 includes at least one communication port 623 (COM1) coupled to a QBB serial bus 602 that interfaces to each processor 240 of the QBB node 200. During a “boot” sequence for each processor 240, the power system manager 610 exchanges command/status information with the respective CPU 241 of each processor 240 over the QBB serial bus 602. For example, the power system manager 610 provides commands to the CPU 241 instructing the respective processor 240 to execute certain self-tests and, upon completion of the tests, the CPUs 241 return their statuses to the power system manager 610 for transmittal to the system control manager 560 via the console serial bus 410. The system control manager 560 thus has complete information of the FRUs in each of the QBB nodes 200 prior to booting the system reference manual console 430 and operating system.

The power system manager 610 is generally responsible for powering-up the FRUs of the QBB node 200, along with managing their self-tests and their populations. To that end, the power system manager 610 performs inventory control functions, including the gathering of specific configuration information used to keep track of each FRU. The power system manager 610 preferably collects this FRU-specific information during an initialization phase of a system power-up sequence over management buses. The FRU-specific information is stored on a non-volatile storage element of each FRU and includes, inter alia, a part number, a serial number, a location and identification of a manufacturer of the FRU, a manufacturing date and error information detected at various stages of operation of the FRU. In a preferred embodiment, the non-volatile storage element comprises a 256-byte, electrically erasable read only memory (EEROM) device and the management buses are I²C buses.

Specifically, the power system manager microcontroller 620 communicates with a plurality of I²C bus controllers 655a, 655b, and 655c (denoted as IIC1-IIC3) located on the power system manager 610, each of which controls a respective I²C bus 650a, 650b, and 650c extending over the QBB backplane 201. The I²C bus controllers 655a-655c retrieve the FRU-specific information stored in the EEROMs 660 located on each FRU in accordance with a conventional protocol. The EEROMs 660 are used for storing configuration and error management information used by the microcontrollers within their subsystems.

As the MDM microcontroller 850 has knowledge of memory device parameters which indicate how much power will be consumed by the installed DIMMs, such as the number of physical memory banks present in the memory/directory carrier module 800, the MDM microcontroller 850 can control the rate at which the memory BIST is run. In a preferred embodiment, the MDM microcontroller 850 is used to preprocess the memory configuration information, and provide a one-bit flag encoded in the self-test polynomial which is then loaded into the memory 900. The bit is used directly in the memory 900 to control the rate at which BIST operations are performed. For example, if the bit is set, BIST operations will occur at half-speed.

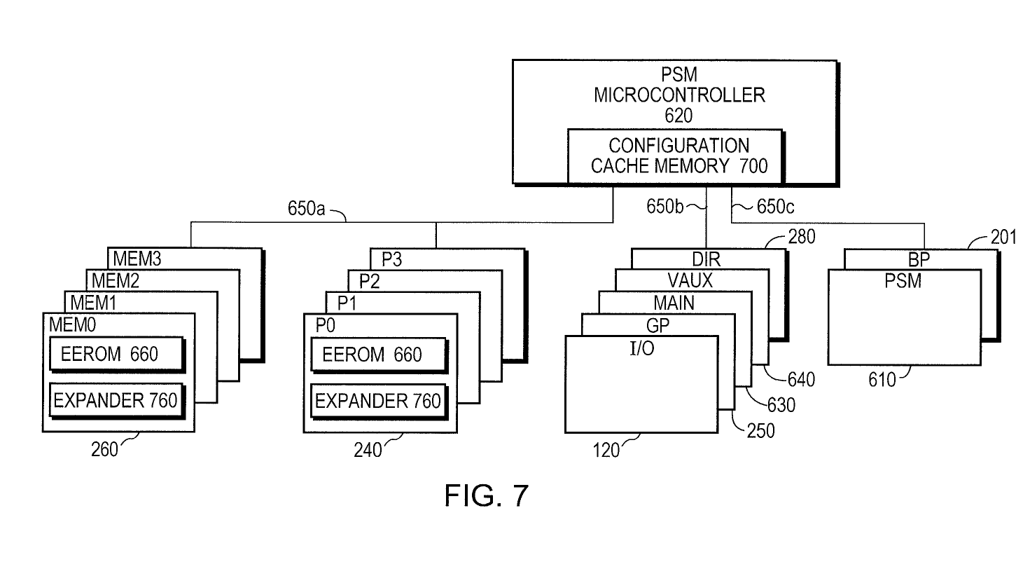

FIG. 7 is a schematic block diagram of the power system manager microcontroller 620 coupled to I²C buses 650a, 650b, and 650c that interconnect various FRUs of a QBB node 200. As explained above, the four processors 240 (P0-P3) and the four memory modules 260 (MEM0-MEM3) of the QBB node 200 are coupled to the first I²C bus 650a. In addition, the directory 280, the main power module 630, the auxiliary power module 640, the global port 250, and the I/O port 120 are connected to the second I²C bus 650b. The QBB backplane 201, together with other QBB FRU modules, such as the power system manager 610, are connected to the third I²C bus 650c.

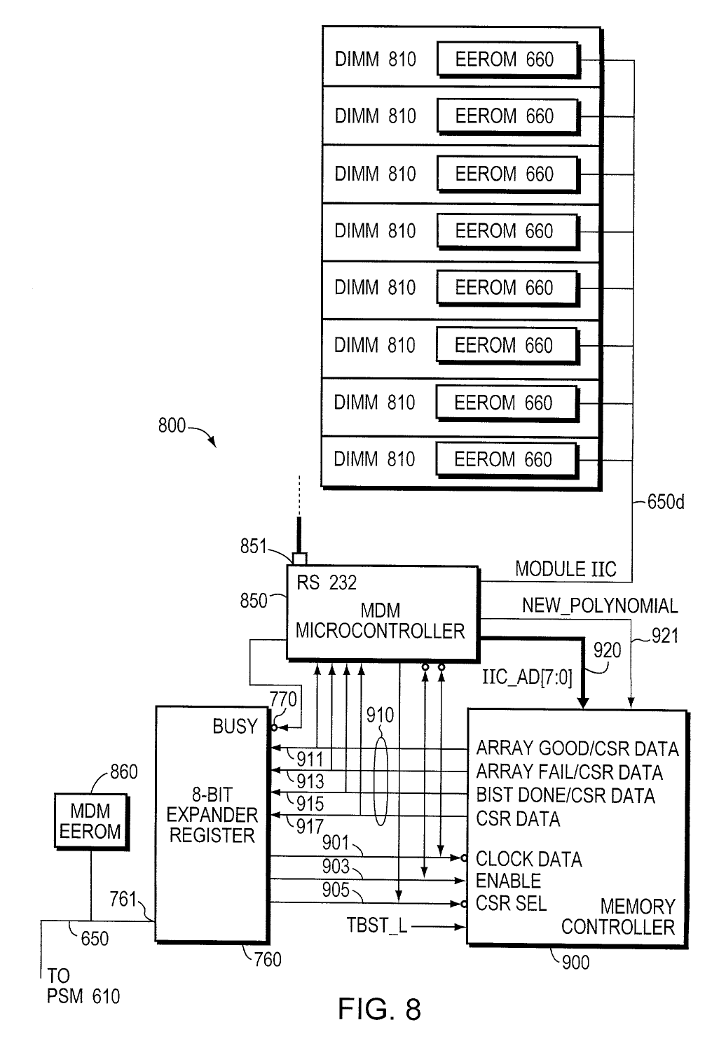

Each processor 240 and each memory module 260 is a FRU that includes an EEROM 660 and an 8-bit expander register 760. The expander register 760 is a control status register that may be accessed over an I²C bus using predetermined bit locations designated for control and status purposes. In addition, as shown in FIG. 8, each DIMM 810 coupled to the memory/directory carrier module 800 is a FRU that includes an EEROM 660 for purposes of storing FRU-specific information associated with the respective memory DIMM 810. The FRU-specific information stored on the EEROMs 660 further include timing parameters (or configuration information from which timing parameters may be calculated) that define the operational speeds and characteristics of the respective DIMM 810. In the illustrative embodiment, each memory/directory carrier module 800 includes a total of eight DIMMs 810 grouped in sets of four.

According to an aspect of the present invention, a circuit is provided for implementing a protocol used by the power system manager 610 to access the EEROMs 660 located on each DIMM 810 of each memory/directory carrier module 800. The memory/directory carrier module 800 comprises a plurality of DIMMs 810 coupled to an MDM microcontroller 850 having internal UART and I²C bus master capabilities, and to a memory controller 900 implemented as an ASIC. It should be noted that the DIMMs 810 are coupled to a module I²C bus 650d with protocol circuitry resident on the memory/directory carrier module 800.

The MDM microcontroller 850 of the MDM carrier is preferably a PIC17C44 processor that comprises an integral part of the console serial bus subsystem 400 when participating in the power-up and self-test flows transmitted over the console serial bus 410. For example, the MDM microcontroller 850 manages the DIMMs 810 by initiating built-in self-tests (BIST) directed to those memories and retrieving the status of the tests to identify a failed DIMM. The MDM microcontroller 850 is also responsible for retrieving FRU-specific information from the EEROMs 660 located on the DIMMs 810 and providing that information to the novel 8-bit expander register 760. The expander register 760 and an MDM EEROM 860 located on the memory/directory carrier module 800 are coupled to the system I²C bus 650. As can be appreciated by one skilled in the relevant art, the system I²C bus 650 cannot accommodate the EEROMs 660 on the DIMM FRUs 810 connected to the memory/directory carrier module 800. Accordingly, the expander register 760 is used to convey the FRU-specific information from the MDM microcontroller 850 to the power system manager microcontroller 620.

In accordance with an aspect of the present invention, a portion (e.g., 4-bits) of the expander register 760 includes a communications port 761 for enabling communication between the power system manager microcontroller 620 and the MDM microcontroller 850. The protocol employed over the communication port 761 comprises various commands exchanged between the power system manager microcontroller 620 and the MDM microcontroller 850. An example of such a command is a request by the power system manager 610 for the MDM microcontroller 850 to acquire FRU-specific information stored in the EEROM 660 of a particular DIMM 810. The power system manager microcontroller 620 preferably requests four bits of information at a time from the MDM microcontroller 850 by addressing each DIMM 810 located on the memory/directory carrier module 800. The FRU-specific information is transferred from each DIMM 810 over the module I²C bus 650d to the MDM microcontroller 850. The eight EEROMs 660 associated with the eight DIMMs 810 represent the maximum number of this device type that can be accessed on the module I²C bus 650d.

The timing parameters stored on the DIMM EEROM 660 (or calculated by the microcontroller 850 for configuration information stored thereon) are used by the memory controller 900 to configure the DIMMs 810. For example, the timing parameters may include access time to various locations of the DIMMs 810 along with the frequency at which these accesses may be performed. In addition, the configuration information includes the number of banks per DIMM 810, along with the number of row and column addresses contained therein. Therefore, it is desirable to provide a means for the memory controller 900 to examine the timing parameters to insure that the particular DIMMs 810 meet system requirements.

According to the invention, the MDM microcontroller 850 provides an improved interface between the memory controller 900 and the DIMMs 810. The improved interface consists of data (8 bits) and control/status/reset used for communications between the MDM microcontroller 850 and the memory controller 900. The external interface allows for both reading from and writing to the EEROMs 660. This configuration provides access to the contents of the EEROMs 660 via an external interface even when the system path to the control status registers of the memory controller 900 has not been established or cannot be established. The MDM microcontroller 850 supports access to this data via a handshake protocol over the improved interface by means of the expander register 760. In order to reduce power consumption and noise (i.e., power supply and electromagnetic interference), the MDM microcontroller 850 may also disable certain DIMM clock phase lock loop (PLL) outputs based on module configuration.

The MDM microcontroller 850 reads configuration data from each DIMM 810 after system reset. A portion of this data is visible to the SMP system 100 via the control status registers. The configuration data read is used by the SMP system 100 to configure the memory/directory carrier modules 800 and for arbiter scheduling purposes. Access to the DIMM EEROM configuration information is realized to meet server management requirements. The memory controller 900 also provides a “fast path” to self test status information and an alternate path to control status register data when normal system channels are uninitialized or non-functional, and during manufacturing testing. When a memory/directory carrier module 800 is installed in the SMP system 100, this data is accessible over the system I²C bus 650 via the expander register 760. During manufacturing test, the data is accessible via an RS232 port 851 on the MDM microcontroller 850.

TABLE I
ASIC Function Flow - Memory

if ASYNC_RESET_L or RESET_MICRO are asserted, assert MICRO_RESET_L
ASIC AUTOREAD FLOW
When ASYNC_RESET_L deasserts or after RESET_MICRO deasserts:

{

read loop:

set pointer to DIMM_CSR_0

for DIMM 0 to DIMM 7

{

for byte=0 to byte=7

{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}
increment DIMM pointer
}

DIMM error information read:

set pointer to DIMM ERROR CSR

for byte=0 to byte=7

{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}

Micro revision information read:

set pointer to ModConfig CSR

{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}

Polynomial Selection:

{
for byte=0 to byte=7
{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}
}

Spin on Stall:

{
if NEW_POLYNOMIAL == 0

check for stalls via handshake

else

reload polynomials via handshake

}
}

TABLE II
ASIC Function Flow - Directory

if ASYNC_RESET_L or RESET_MICRO are asserted, assert MICRO_RESET_L
ASIC AUTOREAD FLOW
When ASYNC_RESET_L deasserts or after RESET_MICRO deasserts:

{

read loop:

set pointer to DIMM_CSR_0

for DIMM 0 to DIMM 7

{

for byte=0 to byte=7

{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}
increment DIMM pointer
}

Micro revision information read:

set pointer to ModConfig CSR

{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}

Polynomial Selection:

{
for byte=0 to byte=31
{
clock byte of data via IIC_MICRO_VALID assertion
assert IIC_ASIC_ACK and shift byte into appropriate CSR
wait for IIC_MICRO_VALID deassertion
deassert IIC_ASIC_ACK
}
}

Spin on Stall:

{
if NEW_POLYNOMIAL == 0

check for stalls via handshake

else

reload polynomials via handshake

}
}

Table I illustrates the power-up flow sequence between the MDM microcontroller 850 and the memory controller 900 to load the required configuration information into the memory controller 900 so that the memory controller 900 can configure itself for self-test. Table II illustrates this procedure for a directory module.

On power-up, the MDM microcontroller 850 queries each DIMM 810 over the module I²C bus 650d. That is, the MDM microcontroller 850 retrieves configuration information stored on the EEROMs 660. The MDM microcontroller 850 retrieves eight bytes of configuration information per DIMM 810 and further generates an additional byte of error information for use by the memory controller 900.

When a system reset signal is removed from an external pin, the MDM microcontroller 850 initiates the retrieval of configuration information from the EEROMs 660. That is, the SMP system 100 powers up in reset and, once reset is removed from the external pin of the MDM microcontroller 850, the configuration information retrieval process begins. Upon retrieving and processing the configuration information, the MDM microcontroller 850 provides the results to the memory controller 900. As part of its processing, the MDM microcontroller 850 “sizes” the DIMMs 810; that is, the MDM microcontroller 850 retrieves pertinent DIMM configuration information such as the number of row and column addresses of each DIMM 810. With this size information acquired, the MDM microcontroller 850 then calculates a polynomial designated by reference number 921, or “seed,” for power up self test that guarantees that every memory location of each DIMM 810 is tested at least once during one pass of a built in self test (BIST) sequence.

The results of the retrieval and calculation process are provided to the memory controller 900. Table III lists the information provided to the memory controller 900 for the memory module, wherein the information includes DIMM-specific configuration information along with the polynomial 921 calculated by the MDM microcontroller 850. During the retrieval and calculation process performed by the MDM microcontroller 850, the SMP system 100 and constituent components (e.g., the quad switch address 220, the quad switch data 230, the processors 240, and their associated clock-forwarded links comprising a system path) are not operational. In fact, the MDM microcontroller 850 and the memory controller 900 perform such processing to determine whether there is good memory in the QBB node 200 for use by these system components.

Micro to ASIC Returned Data—Memory:

The format of data returned to the ASIC from the Micro on Memory modules is as follows:

TABLE III

| BYTE | Location | Description |
|---|---|---|
| 0 | DIMM-0 Byte 13 | SDRAM width |
| 1 | DIMM-0 Byte 3 | Number of Row Addresses on DIMM |
| 2 | DIMM-0 Byte 4 | Number of Column Addresses on |
| | | DIMM |
| 3 | DIMM-0 Byte 5 | Number of Module Banks (RANKS) on |
| | | DIMM |
| 4 | DIMM-0 Byte 9 | SDRAM Cycle Time at max. supported |
| | | CAS latency |
| 5 | DIMM-0 Byte 17 | Number of Banks on each SDRAM |
| 6 | DIMM-0 Byte 23 | Minimum Clock Cycle Time at CAS |
| | | Latency 2 |
| 7 | DIMM-0 Byte 29 | Minimum RAS to CAS delay |
| 8 | DIMM-1 Byte 13 | SDRAM Width |
| . | | |
| . | | |
| 64 | DIMM-0 Error/Status | Microcontroller encoded summary for |
| | | DIMM-0 |
| . | | |
| . | | |
| . | | |
| 71 | DIMM-7 Error/Status | Microcontroller encoded summary for |
| | | DIMM-7 |
| 72 | Micro revision | 3-bit field containing Micro revision |
| | | information |
| 73 | Array-0 Polynomial 0 | First byte of Array-0 Polynomial |
| 74 | Array-0 Polynomial 1 | Second byte of Array-0 Polynomial |
| 75 | Array-0 Polynomial 2 | Third byte of Array-0 Polynomial |
| 76 | Array-0 Polynomial 3 | Fourth byte of Array-0 Polynomial + |
| | | BIST Speed |
| 77 | Array-1 Polynomial 0 | First byte of Array-1 Polynomial |
| 78 | Array-1 Polynomial 1 | Second byte of Array-1 Polynomial |
| 79 | Array-1 Polynomial 2 | Third byte of Array-1 Polynomial |
| 80 | Array-1 Polynomial 3 | Fourth byte of Array-1 Polynomial + |
| | | BIST Speed |
| 81 | Self-Test Stall | Toggle stalling of Self-Test |

Specifically, upon removal of the system reset signal, the MDM microcontroller 850 automatically initiates a sequence to read the pertinent EEROM locations. This read operation is referred to as “autoread.” The MDM microcontroller 850 sequences through the required DIMM configuration locations and performs a predetermined level of checking. The MDM microcontroller 850 then calculates a polynomial for each installed array 265 (for a memory module) or each DIMM 810 (for a directory module) based on the DIMM configuration. The MDM microcontroller 850 stores the information in its local RAM and then initiates a write sequence to the control status registers of the memory controller 900. During the initial phases of the autoread sequence, the MDM microcontroller 850 reads each EEROM 660 for configuration information and stores this information in its local RAM.

A memory controller control status register write sequence is then initiated over a controller interface bus 920 with the MDM microcontroller 850 asserting a signal (I²C micro valid) that informs the memory controller 900 that the MDM microcontroller 850 has completed the configuration read operations and is ready to load that data into the status registers of the memory controller 900. Data is placed on the improved interface one clock tick before the assertion of I²C_micro_valid. Data present on the eight lines of the controller interface bus 920 (i.e., I²C_ad <7:0>) is valid whenever the I²C_micro_valid signal is asserted and is acknowledged by the memory controller 900 via another signal I²C_asic_ack.

For a memory module, the subsequent data valid cycles contain the eight bytes per DIMM, which the memory controller 900 loads into a 64-bit control status register associated with each DIMM 810. Data transmitted next comprises one byte (encoded by the MDM microcontroller 850) of error/status information associated with each DIMM 810 that the memory controller 900 loads into an appropriate byte of a 64-bit register (i.e., DIMMErr). A subsequent byte of information passed to the memory controller 900 contains the revision of the MDM microcontroller 850 that is loaded into a ModConfig register of the memory controller 900. The following eight bytes contain two 32-bit polynomials used for test pattern generation with bit <25> of each polynomial signifying whether the self test should be run at full speed or at half speed, making a total of 81 bytes that are transmitted to the memory controller 900.

For a directory module, a total of 41 bytes of information is transmitted to the memory controller 900. The first 8 bytes comprise one byte per DIMM reflecting the DIMM type, and one bit signifying that the accompanying data is valid. The next byte passed to the memory controller 900 contains the revision of the MDM microcontroller 850 which is loaded into the ModConfig register of the memory controller 900. The subsequent thirty two bytes contain eight 32-bit polynomials used for test pattern generation. This completes the autoread sequence. At this time, the SMP system 100 is free to read the control status register data to determine its validity and configure the memory module and memory subsystem for optimal performance, as well as to verify the consistency in the directory and memory sizes.

The RS232 port 851 allows a local terminal to be “plugged in” and interface to the MDM microcontroller 850 to thereby enable reissue of the retrieval and calculation process by the MDM microcontroller 850. The RS232 port 851 also provides the means to initiate and monitor self-test information processed by the MDM microcontroller 850 in a manufacturing environment. In addition, the configuration information located on the DIMMs 810 may be accessed by the power system manager 610 microcontroller over the system I²C bus through the communication port 761 of the expander register 760.

In accordance with the present invention, the improved interface comprises a plurality of signals from the memory controller 900 processed by the MDM microcontroller 850. These output signals from the memory controller 900 comprise status indicators that specify whether the memory array is good or bad, and whether BIST is complete. Completion of BIST is needed to inform system components that they are free to inquire/access the results of self-test. The memory controller 900 initiates BIST after all of the configuration and polynomial information are loaded into the memory controller 900 from the MDM microcontroller 850 in accordance with an asynchronous handshake over the improved interface. As noted, the memory controller 900 does not interface directly to the DIMMs 810 because of the I²C bus interface issues described above. Furthermore, providing a direct interface on the memory controller 900 would be expensive and impractical since a UART device is required to enable external access via an RS232 port for manufacturing testing and other functions through a local terminal.

Table IV shows the error/status information processed by the MDM microcontroller 850 and provided to the memory controller 900. Once BIST is completed, the system components may access the control status registers or directory DIMM that are loaded with the results of BIST over the clock-forwarded links. The system components may access that information to determine the status of the DIMMs 810, including whether they are functioning properly or, if not, what failed. The power system manager 610 of the console serial bus subsystem 400 may also access the status information pertaining to BIST through the expander register 760.

For server management functions, the configuration information stored in the EEROMs 660 (including size, serial numbers and manufacturer of the DIMMs 810) must be accessible even when the system path to the memory controller 900 over the clock forwarded links is not available. Moreover, this information must be accessible if the memory controller 900 is not functional. Therefore, a “backdoor” path is provided from the power system manager 610 through the communication port 761 of the expander register 760 to the MDM microcontroller 850. Specifically, in accordance with the improved interface and protocol between the power system manager 610, the MDM microcontroller 850 and the expander register 760, an asynchronous handshaking arrangement enables access to the DIMM configuration information over the system I²C bus 650 to the system control manager 560 microcontroller for processing in accordance with server management functions. According to another aspect of the improved interface and protocol, the MDM microcontroller 850 can retrieve BIST results and control status register data from any control status register within the memory controller 900, four bits at a time.

### Micro to ASIC Returned Data—Directory:

The format of data returned to the ASIC from the Micro on Directory modules is as follows:

TABLE IV

| BYTE | Location | Description |
|---|---|---|
| 0 | Valid + DIMM-0 Byte | Bit 7 = Valid, Bits 3:0 = DIMM Type |
| | 0 | |
| 1 | Valid + DIMM-1 Byte | Bit 7 = Valid, Bits 3:0 = DIMM Type |
| | 0 | |
| 2 | Valid + DIMM-2 Byte | Bit 7 = Valid, Bits 3:0 = DIMM Type |
| | 0 | |
| 3 | Valid + DIMM-3 Byte | Bit 7 = Valid, Bits 3:0 = DIMM Type |
| | 0 | |
| 4 | Valid + DIMM-4 Byte | Bit 7 = Valid, Bits 3:0 = DIMM Type |
| | 0 | |
| 5 | Valid + DIMM-5 Byte | Bit 7 = Valid, Bits 3:0 = DIMM Type |
| | 0 | |
| 6 | Valid + DIMM-6 Byte | Bit 7 = Valid, Bits 3:0 = DIMM Type |
| | 0 | |
| 7 | Valid + DIMM-7 Byte | Bit 7 = Valid, Bits 3:0 = DIMM Type |
| | 0 | |
| 8 | Micro revision | 3-bit field containing Micro revision |
| 9 | DIMM-0 Polynomial 0 | First byte of DIMM-0 Polynomial |
| . | | |
| . | | |
| 12 | DIMM-0 Polynomial 3 | Fourth byte of DIMM-0 Polynomial |
| 13 | DIMM-1 Polynomial 0 | First byte of DIMM-1 Polynomial |
| . | | |
| . | | |
| 40 | DIMM-7 Polynomial 3 | Fourth byte of DIMM-7 Polynomial |
| 81 | Self-Test Stall | Toggle stalling of Self-Test |

System to DIMM Read/Write Protocol

The read/write protocol between the power system manager 610 of the console serial bus subsystem 400 and the DIMM 810 is conducted over the system I²C bus 650. Specifically, two signals (I²C_micro_enable and I²C_clk_data) are supplied via the expander register 760 and MDM microcontroller 850 to control the flow of data over a 4-bit bidirectional data path between the MDM microcontroller 850 and memory controller 900 and the system I²C bus 650 via the expander register 760. Another signal (I²C_micro_busy), generated by the MDM microcontroller 850 over a data line 770, informs the SMP system 100 (via an expander port) that the MDM microcontroller 850 is busy performing an operation. Once the I²C_micro_busy signal is negated, the SMP system 100 is free to initiate another command or to retrieve data in the case of a EEROM 660 read operation. The I²C_micro_busy signal is also asserted by the MDM microcontroller 850 during the autoread sequence.

Upon assertion of the I²C_micro_enable signal to the MDM microcontroller 850, a sequence is initiated which writes (stores) command information to the MDM microcontroller 850 via the 4-bit data path. The command sequence appears as follows:

Nibble-0 bit <3>=read low, write high, bit <2:0>contains the DIMM ID

Nibble-1 bit <3:0>=address offset-low nibble

Nibble-2 bit <3:0>=address offset-high nibble

Nibble-3 bit <3:0>=write data-low nibble if write operation (not used if read operation)

Nibble-4 bit <3:0>=write data-high nibble if write operation (not used if read operation)

For a read transaction, the first (low) nibble of read data is available at the data port 910 of the MDM microcontroller 850 upon the MDM microcontroller 850 deasserting the I²C_micro_busy signal. The SMP system 100 then prompts for the second nibble of read data by pulsing a I²C_clk_data line. The MDM microcontroller 850 then places the second (high) nibble on the data port. The MDM microcontroller 850 is capable of supplying the second nibble of data faster than the expander can issue the second read command; therefore the system need not poll the busy line for this data word. For a write transaction, the transaction is completed once the fourth nibble is strobed into the MDM microcontroller 850. It is assumed that the MDM microcontroller 850 is capable of capturing the second nibble of write data before the expander register 760 changes or removes the data. The read and write transactions are considered complete when the system deasserts the I²C_micro_enable signal over a control line 903.

During normal system operation, self-test status information is available to the SMP system 100 via the I²C connection between the expander register 760 and the memory controller 900. By first writing a data pattern of, e.g., 1111111(b) to the expander register 760, the SMP system 100 can then perform a read operation of the self-test status information from the memory controller 900 via the expander register 760. Returned data is formatted as, e.g., bit <7>=not valid, bit <6>=self-test complete, bit <5>=at least 1 array/DIMM failed, bit <4>=at least 1 good array/DIMM exists, and bits <3:0>=not valid.

In the event that the SMP system 100 wishes to retrieve control status register data via the I²C bus 650, it is possible to retrieve data from the memory controller 900 via the expander register 760. This may become necessary in situations where normal system channels are not functional. By first writing a data pattern of 1111101(b) to the expander register 760, the SMP system 100 can then read the first nibble of control status register data from the upper four bits of the expander register 760. The next transaction must be a write operation of, e.g., 11111100(b) followed by a write operation of 11111101(b) which instructs the memory controller 900 to increment to the next nibble. The SMP system 100 is now free to read the second nibble of the control status register data. This sequence continues until all control status register locations have been read. If the SMP system 100 decides to terminate the control status register read process early, it must clear a signal (I²C_mpa_csr_sel) on a control line 905 by performing a write operation to the expander register 760 of, e.g., 11111111(b). This insures that the counters inside the memory controller 900 are reset properly before the next control status register read attempt.

Self-test status and control status register information are also available to the MDM microcontroller 850; however, access by the MDM microcontroller 850 and the expander register 760 is mutually exclusive. Typically, the MDM microcontroller 850 accesses this information only in a manufacturing environment via the RS232 port to determine the results of BIST and aid with debug operations. After initiating a self-test cycle, the MDM microcontroller 850 can monitor the state of self-test status lines which are connected directly to input pins. In order to do this, the MDM microcontroller 850 insures that the I²C_clk_data control line 901, the I²C_micro_enable control line 903, and the I²C_mpa_csr_sel control line 905 are deasserted (high). The MDM microcontroller 850 can also retrieve control status register data via a protocol similar to the expander register 760 access method. Specifically, the MDM microcontroller 850, i) asserts the I²C_mpa_csr_sel signal; ii) reads the state of the I²C data lines (the first control status register nibble) three clock cycles later; iii) asserts the I²C_clk_data signal; iv) deasserts the I²C_clk_data signal; v) reads the next nibble of control status register information; and vi) continues asserting I²C_clk_data etc. This 4-bit interface to the control status register data is also referred to as the “backdoor” interface.

Test verification during manufacturing can be provided at the RS232 port 851 of the MDM microcontroller 850. In this application, the MDM microcontroller 850 is used to interface between the DIMMs 810 and the memory controller 900 to initiate BIST operations and manipulate the data returned from the DIMMs 810 (including the BIST results). These operations may be performed even when the backplane 201 of a QBB node 200 is not operational, with the exception of power to the module being provided. The protocol used by the MDM microcontroller 850 to access the self-test and control status register information is described above in accordance with the improved interface between the MDM microcontroller 850, the DIMMs 810, and the memory controller 900.

Broadly stated, there are four control status register data information bits and three BIST status bits available over the improved interface. If the control status register data bits are used to retrieve control status register data from the control status register registers of the memory controller 900, the I²C_mpa_csr_sel signal is asserted to configure a multiplexer within the memory controller 900 to select the control status register data (four bits at a time) from a control status register block of the memory controller 900. A four-bit portion of the novel interface data path may be used for either control status register data or BIST status, and the I²C_mpa_csr_sel signal determines whether an internal multiplexer of the memory controller 900 selects data from a BIST state machine or from the control status register data block.

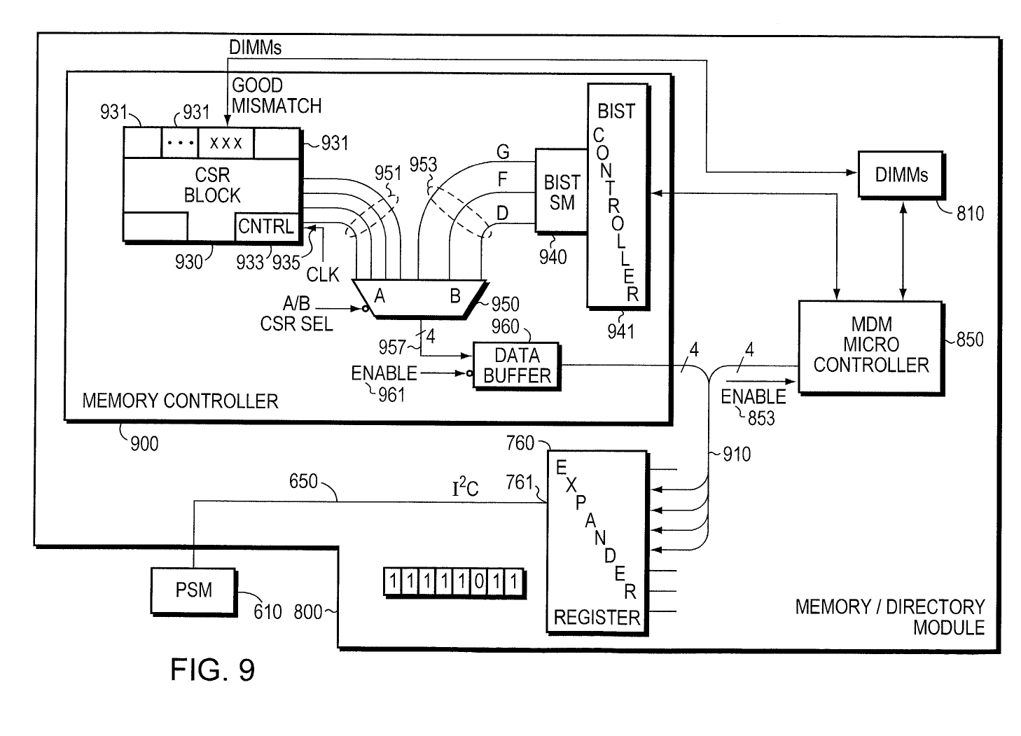

FIG. 9 is a schematic block diagram showing the internals of the memory controller 900 including a control status register block 930 and a BIST state machine 940, each having outputs coupled to inputs of a multiplexer 950. The control status register block 930 includes a plurality of control status data registers 931, each of which is 64 bits wide (32 bits wide for the directory). The data in the control status data registers 931 may be provided over the novel interface at a rate of four bits at a time. Therefore, control logic circuitry 933 is located on the control status register block 930 that, in response to a clock data input signal 935, steps through the addresses of the control data status registers 931 four bits at a time. For a memory module, the control status register block 930 preferably contains sixty-four 64-bit control status data registers 931. For a directory module, the control status register block 930 contains one hundred and twenty-eight 32-bit control status data registers 931. The granularity of the addressing is four bits because there are four data lines on the improved interface and communication port 761 of the expander 760.

Specifically, four data lines 951 are provided from the control status register block 930 to the input A of the multiplexer 950 while three lines 953 are provided from the BIST state machine 940 to input B of the multiplexer 950. The three outputs of the BIST state machine 940 pertain to BIST status such as good (G), fail (F) and done (D) signals. The state of the control status register select signal provided through the expander 760 determines whether input A or B is selected by the multiplexer 950 for output over a 4-bit output line 957. The clock data signal is provided to counters within the control logic circuitry 933 of the control status register block 930 to enable the stepping function through addresses (nibbles) of the control status data registers 931.

The first four bits of the first nibble (starting at address 0) are always the first data lines provided over the control status register data lines 951 when the I²C_mpa_csr_sel signal enables the input A of the multiplexer 950. The next time the clock data signal is asserted, the next nibble of information is provided over the data lines 951. This continues sequentially through each control status data registers 931 until the sequence wraps around to the initial nibble. Alternatively, by releasing the I²C_mpa_csr_sel signal line, the counters in the control interface logic 933 reset to the initial nibble of the initial control status data register 931 (address 0).

The BIST state machine 940 is loaded with input data from the MDM microcontroller 850 via a BIST controller 941 coupled to the BIST state machine 940. That is, the MDM microcontroller 850 retrieves the configuration information from the DIMMs 810 and processes it before providing the results to the BIST controller 941. On the other hand, the control status register data is loaded into the control status data registers 931 based upon the results of the BIST. Upon initiating BIST, the BIST state machine 940 instructs the memory controller 900 to verify the data by counting through the address locations and testing them accordingly. It should be understood that the memory port address 261 (in FIG. 2) is the ASIC which interfaces with the DIMM address and control lines, and the memory port data 263 is the ASIC which interfaces with the DIMM data lines.

The data retrieved from the memory port data 263 are compared at the memory port data 263 and, depending upon the results of the comparison, the control status data registers 931 (in FIG. 9) are loaded with either good or mismatched indicators. The operation compares the expected data with the data actually retrieved from the DIMMs 810. The output of the multiplexer 950 is loaded into a data buffer 960 that is enabled by an enable signal 961 provided from the expander register 760. Depending upon the state of the enable signal 961, either the data buffer 960 or the MDM microcontroller 850 has access to the 4-bit data path of the improved interface for purposes of exchanging information with the expander register 760. The enable signal 961 is also provided to the MDM microcontroller 850 at a port 853. Thus, the data path of the improved interface may be controlled to enable reading/writing of the configuration information from the DIMMs 810 directly through the MDM microcontroller 850 or to enable access to the CSR data or BIST results through the memory controller 900. The power system manager 610 may generate the enable signal 961 by way of the expander register 760. Moreover, the I²C_mpa_csr_sel signal is also essentially provided by the power system manager 610 by way of the expander register 760 or by the microcontroller 850. However, the clock data signal on the control line 901 is generated by the expander register 760 or by the microcontroller 850 whenever it is able to receive a nibble of data.

In particular, the input 761 of the expander register 760, coupled to the I²C bus 650, is capable of receiving a stream of serial data. This serial data is provided over the system I²C bus 650 from the power system manager 610 and each bit corresponds to an input/output of the expander register 760 (i.e., 8 input/output lines). The interface with the expander register 760 and the improved asynchronous interface between the MDM microcontroller 850 and memory controller 900 may be either an input or output interface depending upon the state of the serial bit stream provided over the I²C bus 650. For example, if each bit of the input serial stream is asserted high, then the interface of the expander register 760 with the improved asynchronous interface comprises inputs from that improved interface. The interface of the expander register 760 may also be an output to the improved asynchronous interface on a per bit basis if the input stream is deasserted low.

The interface between the expander register 760, the memory controller 900, and MDM microcontroller 850 preferably comprises tri-state signal lines so that either the MDM microcontroller 850 or the expander register 760 can control the data path with respect to the memory controller 900. For example, assume the MDM microcontroller 850 is instructed by the power system manager 610 (via the expander register 760) to retrieve data from a particular location of the DIMM 810 modules. While accessing the DIMM locations over the module I²C bus 650d, the MDM microcontroller 850 asserts a busy signal over the control line 770 to the expander register 760. The power system manager 610 continually polls the expander register 760 to determine the state of the control line 770 to determine when the requested data has been retrieved by the MDM microcontroller 850 and is available for the power system manager 610. As soon as the busy signal goes away, the power system manager 610 can then retrieve those results from the expander register 760 over the system I²C bus 650.

The foregoing description has been directed to specific embodiments of the present invention. It will be apparent, however, that other variations and modifications may be made to the described embodiments, with the attainment of some or all of their advantages. Therefore, it is the object of the appended claims to cover all such variations and modifications as come within the true spirit and scope of the invention.

What is claimed is:

1. A memory/directory carrier module comprising:
one or more memory devices, each memory device having a buffer for storing configuration information for the respective memory device;
an inter-integrated circuit (I²C) bus coupled to each buffer of the one or more memory devices;
a programmable microcontroller coupled to the I²C bus, the microcontroller configured to access the configuration stored in the one or more buffers via the I²C bus and calculate corresponding power consumption parameters; and
a memory controller configured to control read/write access to the one or more memory devices, the memory controller coupled to the programmable microcontroller,
wherein
the programmable microcontroller reads configuration information from the one or more buffers via the I²C bus, calculates the power consumption parameters, and provides the calculated power consumption parameters to the memory controller.

2. The memory/directory carrier module of claim 1 wherein
the memory controller has at least one control status register (CSR) for each memory device, and
the programmable microcontroller writes the calculated timing parameters into respective CSRs of the memory controller.

3. The memory/directory carrier module of claim 2 wherein the memory controller utilizes the calculated power consumption parameters to control the rate at which a built-in self test (BIST) operation is performed on one or more memory devices.

4. The memory/directory carrier module of claim 3 wherein the programmable microcontroller is further configured to generate a polynomial for use by the one or more memory devices in performing the BIST, and to load each polynomial into the respective CSR registers of the memory controller.

5. The memory/directory carrier module of claim 4 wherein the programmable microcontroller is further configured to encode a flag into the polynomial provided to the memory controller, the flag corresponding to the power consumption rate of the respective memory device.

6. The memory/directory carrier module of claim 5 wherein the speed at which the BIST of a given memory device is performed is reduced in response to the corresponding flag being set.

7. The memory/directory carrier module of claim 6 wherein the speed is reduced by half.

8. The memory/directory carrier module of claim 7 wherein the flag is a single bit.

9. The memory/directory carrier module of claim 8 wherein the one or more memory devices are dual in line memory modules (DIMMs).

10. The memory/directory carrier module of claim 9 wherein the memory controller is an application specific integrated circuit (ASIC).

11. The memory/directory carrier module of claim 1 wherein the microcontroller further provides configuration information to the memory controller.
